(19) United States
(12) Patent Application Publication
(10) Pub. No.: US 2013/0207129 A1
(43) Pub. Date: Aug. 15, 2013

(54) Light-Emitting Diode Area Light Module and Method for Packaging the Same

(71) Applicants: Chin-Lung LIN, Taipei City (TW); Yen-Chang TU, Taipei City (TW); Pai-Ti LIN, Taipei City (TW); Che-Chang HU, Taipei City (TW)

(72) Inventors: Chin-Lung LIN, Taipei City (TW); Yen-Chang TU, Taipei City (TW); Pai-Ti LIN, Taipei City (TW); Che-Chang HU, Taipei City (TW)

(73) Assignee: UNISTAR OPTO CORPORATION, TAIPEI CITY (TW)

(21) Appl. No.: 13/372,432

(22) Filed: Feb. 13, 2012

(51) Int. Cl. H01L 33/48; B23K 31/02

(52) U.S. Cl. 257/88; 228/176; 257/E33.056

(57) ABSTRACT

An LED area light module has a substrate and a circuit layer and a solder mask layer formed on the substrate. The solder mask layer partially covers the circuit layer for the partially exposed circuit layer to form multiple electrical contacts. An embankment wall is formed on the solder mask layer with a solder mask material for the electrical contacts to be located within the embankment wall. Multiple LED chips are mounted on the solder mask layer within the embankment wall and electrically connected to the electrical contacts. Optically-transmissive adhesive is filled and concentrated within the embankment wall and covers the LED chips by a tension force thereof, and forms an optically-transmissive adhesive layer after congealed. Accordingly, the LED area light module eliminates the use of thick frame made of metal or rubber and steps of manufacturing and mounting the frame to simplify the packaging processes.

### BACKGROUND OF THE INVENTION

1. Field of the Invention

The present invention relates to a light-emitting diode (LED) area light module and a method for packaging the same and more particularly to an LED area light module eliminating a thick frame and steps for producing the thick frame and laminating the thick frame on the LED area light.

2. Description of the Related Art

In view of rapid development of LEDs, LEDs have gradually replaced conventional light bulbs to become lighting elements of light sources for most lighting equipment. As light transmitted by LED transistors has high directivity, a conventional LED area light module is built to have multiple LED chips embedded in optically-transmissive adhesive to form a uniform area light source good for lighting equipment.

With reference to FIGS. 5 and 6, the conventional area light module has a substrate 70, a frame 80, multiple LED chips 90 and an optically-transmissive adhesive layer 100.

The substrate 70 has a circuit layer 71 and a solder mask layer 72. The circuit layer 71 is formed on a surface of the substrate 70. The solder mask layer 72 partially masks the circuit layer 71 and the circuit layer 71 is partially exposed to form multiple electrical contacts 73.

The frame 80 is thick, is formed of metal or rubber and is laminated on the solder mask layer 72 of the substrate 70 so that the electrical contacts 73 are mounted within and surrounded by the frame 80.

The LED chips 90 are securely mounted on the solder mask layer 72 of the substrate 70 and within the frame 80, and are electrically connected to the respective electrical contacts 73.

The optically-transmissive adhesive layer 100 is formed within the frame 80 to cover the LED chips 90.

Before forming the optically-transmissive adhesive layer 100, the thick frame 80 must be prepared beforehand, and the frame 80 is then laminated on the solder mask layer 72 of the substrate 70. The optically-transmissive adhesive layer 100 is formed by filling transparent adhesive or fluorescent adhesive in the frame 80 until the transparent adhesive or fluorescent adhesive is congealed, so as to surround the LED chips 90.

Besides the manufacture of the thick frame 80, the manufacturing process of the conventional LED area light module needs to laminate the frame 80 on the solder mask layer 72 and the step is inconvenient and time-consuming Also because all the thick frames 80 are made of aluminum or rubber, the produced aluminum frame or rubber frame is far thicker than the LED chips 90. To prevent the thick frame 80 from blocking light emitted from the LED chips 90, the optically-transmissive adhesive layer 100 should be the same as the frame 80 in thickness. Such a prerequisite not only costs more materials but also gives rise to an unnecessary light-focusing effect generated as a result of a concave arc surface formed because the transmissive adhesive layer 100 is thicker than the frame 80. Such light-focusing effect is unfavorably against uniformly scattering light and needs to be overcome accordingly.

### SUMMARY OF THE INVENTION

An objective of the present invention is to provide an LED area light module and a method for packaging an LED area light module targeting at resolving technical drawbacks of inconvenient and time-consuming production process and more material used.

To achieve the foregoing objective, the LED area light module has a substrate, an embankment wall, multiple LED chips and an optically-transmissive adhesive layer.

The substrate has a circuit layer and a solder mask layer. The circuit layer is formed on a surface of the substrate. The solder mask layer partially covers the circuit layer for the circuit layer to be partially exposed and have multiple electrical contacts formed on the exposed portion of the circuit layer.

The embankment wall is composed of a solder mask material and formed on the solder mask layer for the electrical contacts to be located within the embankment wall.

The LED chips are securely mounted on the solder mask layer and within the embankment wall and are electrically connected to the electrical contacts.

The optically-transmissive adhesive layer is formed within the embankment wall and covers the LED chips.

The embankment wall is formed on the solder mask layer with a solder mask material. After the embankment wall is formed and the optically-transmissive adhesive layer is filled in the embankment wall, the optically-transmissive adhesive is concentrated in the embankment wall due to a tension force thereof so as to cover the LED chips. Hence, no thick frame is required to be made, and the steps of manufacturing the thick frame and mounting the thick frame on the substrate are unnecessary, which simplifies the production processes.

Additionally, as the embankment wall is thinner than each LED chip, less optically-transmissive adhesive is required to fill in the embankment wall. The optically-transmissive adhesive layer also easily protrudes beyond the embankment wall to form a convex arc surface generating a light-scattering effect.

To achieve the foregoing objective, the method for packaging an LED area light module has steps of:

providing a substrate, forming a circuit layer on the substrate and forming a solder mask layer on the circuit layer for the circuit layer to be partially exposed to form multiple electrical contacts;

forming an embankment wall on the solder mask layer of the substrate with a solder mask material for the electrical contacts to be located within the embankment wall;

mounting multiple LED chips within the embankment wall of the substrate and electrically connecting the LED chips to the electrical contacts; and

filling optically-transmissive adhesive in the embankment wall to form an optically-transmissive adhesive layer after the optically-transmissive adhesive is congealed.

In the aforementioned steps, the method for packaging an LED area light module can eliminate the steps of manufacturing a thick frame and mounting the thick frame on the solder mask layer of the substrate, thereby simplifying the production processes for packaging the LED area light module.

Other objectives, advantages and novel features of the invention will become more apparent from the following detailed description when taken in conjunction with the accompanying drawings.

### BRIEF DESCRIPTION OF THE DRAWINGS

FIG. 1 is a top view of an LED area light module having no embankment wall and transmissive adhesive layer in accordance with the present invention;

FIG. 2 is a top view of the LED area light module in FIG. 1 having an embankment wall and a transmissive adhesive layer;

FIG. 3 is a cross-sectional side view of the LED area light module in FIG. 2;

FIG. 4 is a block diagram of method for packaging the LED area light module in FIG. 2;

FIG. 5 is a top view of a conventional LED area light module; and

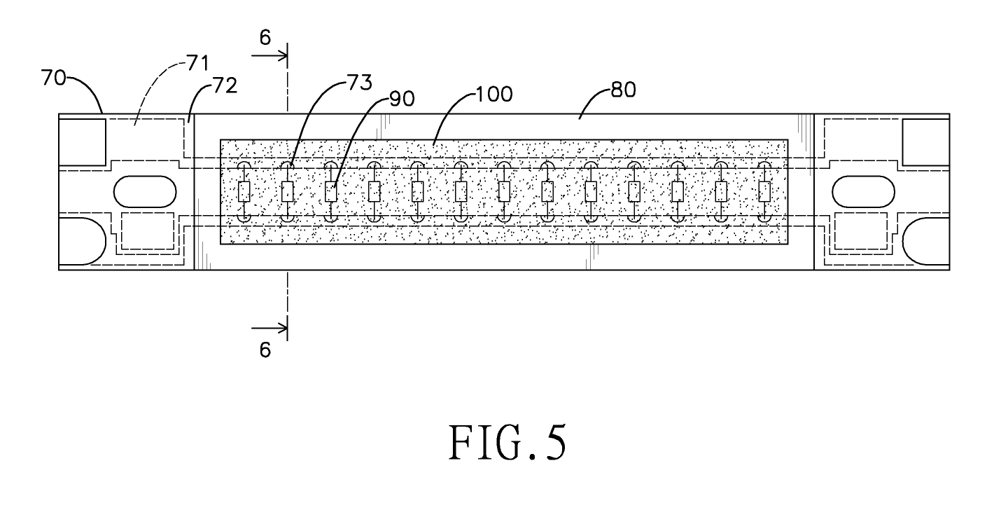

FIG. 6 is a cross-sectional side view of the conventional LED area light module in FIG. 5.

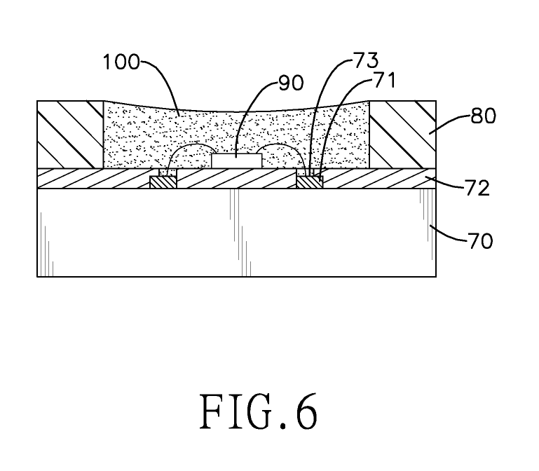

### DETAILED DESCRIPTION OF THE INVENTION

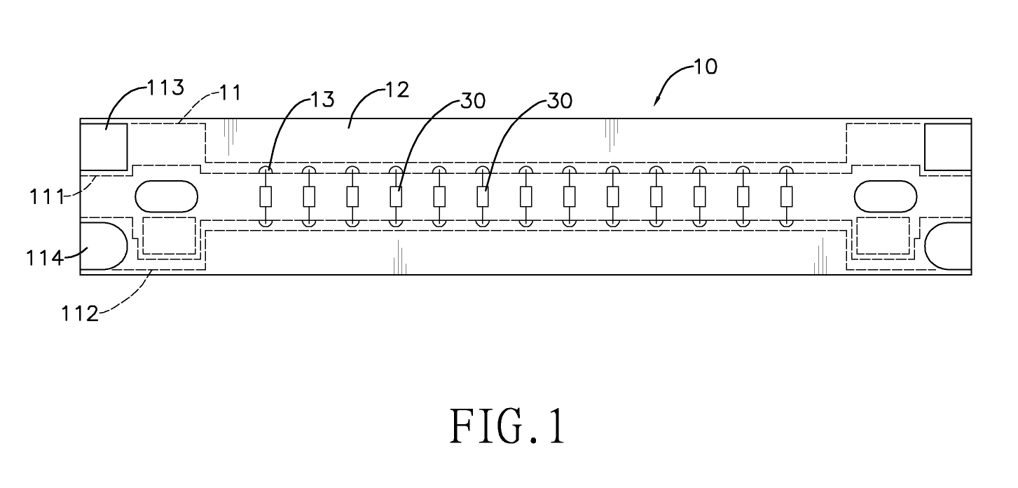

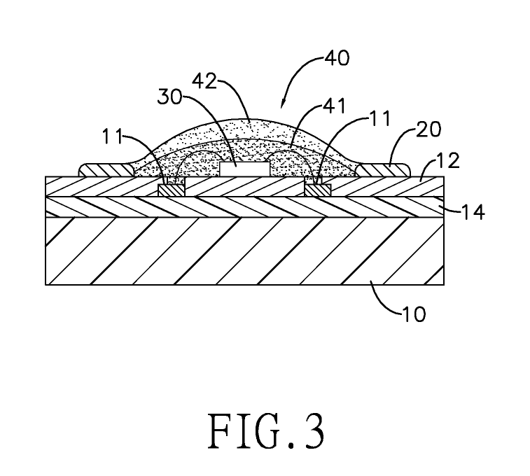

With reference to FIGS. 1 to 3, an LED area light module in accordance with the present invention has a substrate 10, an embankment wall 20, multiple LED chips 30 and an optically-transmissive adhesive layer 40.

The substrate 10 has a circuit layer 11 and a solder mask layer 12. The circuit layer 11 is formed on a surface of the substrate 10. The solder mask layer 12 partially masks the circuit layer 11 so that the circuit layer 11 is partially exposed to have multiple electrical contacts 13 formed on the exposed portion. In the present embodiment, the circuit layer 11 has a positive side circuit 111 and a negative side circuit 112. Two opposite terminals of the positive side circuit 111 are respectively exposed from two sides of the substrate 10 to form two positive contacts 113. Two opposite terminals of the negative side circuit 112 are respectively exposed from two sides of the substrate 10 to form two negative contacts 114. The positive contacts 113 and the negative contacts 114 serve to be connected to an external power source.

The embankment wall 20 is composed of a solder mask material and is formed on the solder mask layer 12 for the electrical contacts 13 to be located within the embankment wall 20.

The LED chips 30 are securely mounted on the solder mask layer 12 and within the embankment wall 20 and are electrically connected to the electrical contacts 13.

The optically-transmissive adhesive layer 40 is formed on the solder mask layer 12 within the embankment wall 20 to cover the LED chips 30. In the present embodiment, the optically-transmissive adhesive layer 40 may be formed by congealed transparent adhesive or fluorescent adhesive, and may have a transparent portion 41 and a fluorescent portion 42.

The substrate 10 may be a metal substrate and further have an insulation layer 14 formed on the surface of the substrate 10 for the circuit layer 11 to be further formed on the insulation layer 14 for the purpose of dissipating heat generated from the LED chips 30.

The embankment wall 20 is less than or equal to each LED chip 30 in thickness. Preferably, the thickness of the embankment 20 is in a range of 0.5 to 1 time of the thickness of each LED chip 30. As the optically-transmissive adhesive layer 40 is thicker than the embankment wall 20, a convex arc surface therefore protrudes beyond the embankment wall 20 to scatter light emitted from the LED chips 30.

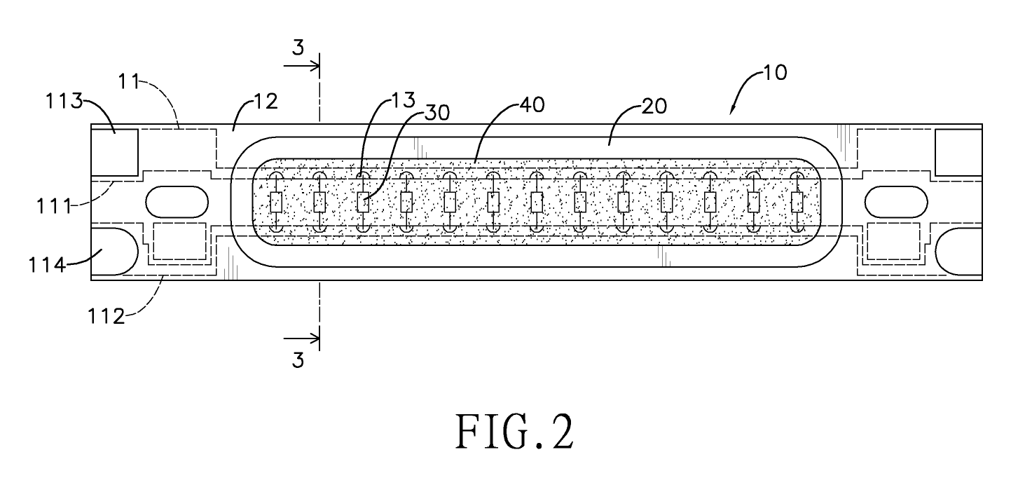

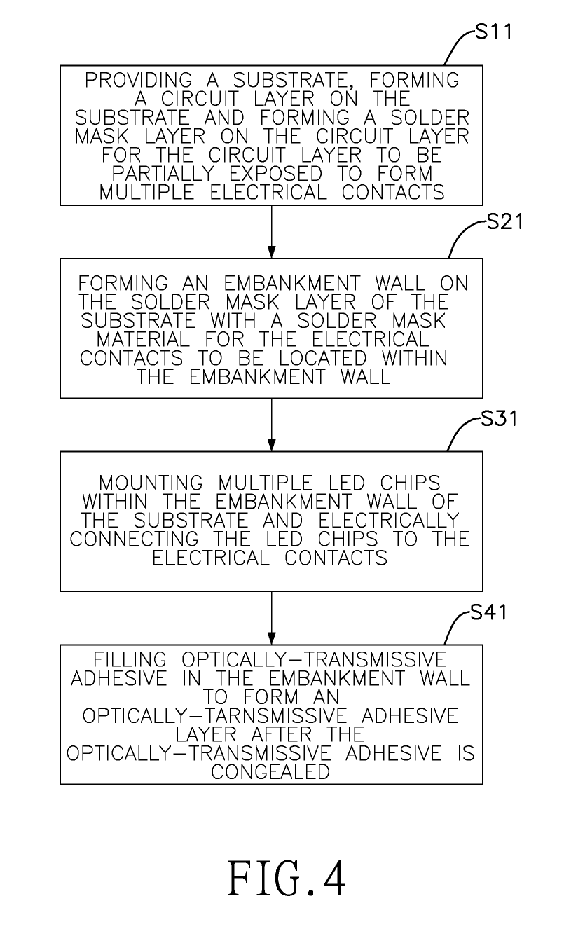

With reference to FIG. 4, a method for packaging the LED area light module in FIG. 2 has the following steps.

Step S11: Providing a substrate 10, forming a circuit layer 11 on the substrate 10, and forming a solder mask layer 12 on the circuit layer 11 for the circuit layer to be partially exposed to form multiple electrical contacts 13. In the present embodiment, the substrate 10 is a metal substrate, an insulation layer 14 is formed on a surface of the substrate 10, and the circuit layer 11 is further formed on the insulation layer 14.

Step 21: Forming an embankment wall 20 on the solder mask layer 12 of the substrate 10 with a solder mask material for the electrical contacts 13 to be located within the embankment wall 20.

S31: Mounting multiple LED chips 30 within the embankment wall 20 of the substrate 10 and electrically connecting the LED chips 30 to the electrical contacts 13.

S41: Filling optically-transmissive adhesive in the embankment wall 20 to form an optically-transmissive adhesive layer 40 after the optically-transmissive adhesive is congealed. In the present embodiment, transparent adhesive and fluorescent adhesive are filled to form the optically-transmissive adhesive layer 40. Alternatively, transparent adhesive or fluorescent adhesive is filled to form the optically-transmissive adhesive layer 40.

The present invention is characterized by the embankment wall 20 formed on the solder mask layer 12 with a solder mask material for the optically-transmissive adhesive layer 40 to be formed within the embankment wall 20. As the surface tension is high when the filled optically-transmissive adhesive is formed and colloidal, the optically-transmissive adhesive is concentrated within the embankment wall 20 to cover the LED chips 30 distributed within the embankment wall 20 and form the optically-transmissive adhesive layer 40 after the optically-transmissive adhesive is congealed. Accordingly, no thick frame is required, and the steps for producing the frame and laminating it on the substrate are unnecessary. Since the embankment wall 20 is thinner than each LED chip, light emitted from the LED chips 30 is not blocked, and less optically-transmissive adhesive is needed. Besides saving material, the LED area light module of the present invention just needs small amount of optically-transmissive adhesive to make the optically-transmissive adhesive layer thicker than the embankment wall 20, and has a convex arc surface formed on the optically-transmissive adhesive layer generating a light scattering effect.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. An LED area light module comprising:
a substrate having:
a circuit layer formed on a surface of the substrate; and
a solder mask layer partially covering the circuit layer for the circuit layer to be partially exposed and having multiple electrical contacts formed on the exposed portion of the circuit layer;
an embankment wall composed of a solder mask material and formed on the solder mask layer for the electrical contacts to be located within the embankment wall;
multiple LED chips securely mounted on the solder mask layer and within the embankment wall and electrically connected to the electrical contacts; and
an optically-transmissive adhesive layer formed within the embankment wall and covering the LED chips.

2. The LED area light module as claimed in claim 1, wherein the embankment wall is less than or equal to each LED chip in thickness.

3. The LED area light module as claimed in claim 2, wherein a thickness of the embankment wall is in a range of 0.5 to 1 time of a thickness of each LED chip.

4. The LED area light module as claimed in claim 3, wherein the optically-transmissive adhesive layer is thicker than the embankment wall and forms a convex arc surface protruding beyond the embankment wall.

5. The LED area light module as claimed in claim 4, wherein the optically-transmissive adhesive layer has a transparent portion and a fluorescent portion.

6. The LED area light module as claimed in claim 1, wherein the substrate is a metal substrate and has an insulation formed on the surface of the substrate for the circuit layer to be formed on the insulation layer.

7. The LED area light module as claimed in claim 2, wherein the substrate is a metal substrate and has an insulation formed on the surface of the substrate for the circuit layer to be formed on the insulation layer.

8. The LED area light module as claimed in claim 3, wherein the substrate is a metal substrate and has an insulation formed on the surface of the substrate for the circuit layer to be formed on the insulation layer.

9. The LED area light module as claimed in claim 4, wherein the substrate is a metal substrate and has an insulation formed on the surface of the substrate for the circuit layer to be formed on the insulation layer.

10. The LED area light module as claimed in claim 5, wherein the substrate is a metal substrate and has an insulation formed on the surface of the substrate for the circuit layer to be formed on the insulation layer.

11. The LED area light module as claimed in claim 6, wherein the circuit layer has:
a positive side circuit, wherein two opposite terminals of the positive side circuit are respectively exposed from two sides of the substrate to form two positive contacts; and
a negative side circuit, wherein two opposite terminals of the negative side circuit are respectively exposed from two sides of the substrate to form two negative contacts.

12. The LED area light module as claimed in claim 7, wherein the circuit layer has:
a positive side circuit, wherein two opposite terminals of the positive side circuit are respectively exposed from two sides of the substrate to form two positive contacts; and
a negative side circuit, wherein two opposite terminals of the negative side circuit are respectively exposed from two sides of the substrate to form two negative contacts.

13. The LED area light module as claimed in claim 8, wherein the circuit layer has:
a positive side circuit, wherein two opposite terminals of the positive side circuit are respectively exposed from two sides of the substrate to form two positive contacts; and
a negative side circuit, wherein two opposite terminals of the negative side circuit are respectively exposed from two sides of the substrate to form two negative contacts.

14. The LED area light module as claimed in claim 9, wherein the circuit layer has:
a positive side circuit, wherein two opposite terminals of the positive side circuit are respectively exposed from two sides of the substrate to form two positive contacts; and
a negative side circuit, wherein two opposite terminals of the negative side circuit are respectively exposed from two sides of the substrate to form two negative contacts.

15. The LED area light module as claimed in claim 10, wherein the circuit layer has:
a positive side circuit, wherein two opposite terminals of the positive side circuit are respectively exposed from two sides of the substrate to form two positive contacts; and
a negative side circuit, wherein two opposite terminals of the negative side circuit are respectively exposed from two sides of the substrate to form two negative contacts.

16. A method for packaging an LED area light module comprising steps of:
providing a substrate, forming a circuit layer on the substrate, forming a solder mask layer on the circuit layer for the circuit layer to be partially exposed to form multiple electrical contacts;
forming an embankment wall on the solder mask layer of the substrate with a solder mask material for the electrical contacts to be located within the embankment wall;
mounting multiple LED chips within the embankment wall of the substrate and electrically connecting the LED chips to the electrical contacts; and
filling optically-transmissive adhesive in the embankment wall to form an optically-transmissive adhesive layer after the optically-transmissive adhesive is congealed.

17. The method as claimed in claim 16, wherein in the step of forming the embankment wall, a thickness of the embankment wall is in a range of 0.5 to 1 time of a thickness of each LED chip.

18. The method as claimed in claim 16, wherein in the step of filling optically-transmissive adhesive in the embankment wall, the optically-transmissive adhesive layer is thicker than the embankment wall.
